(19) United States
(12) Patent Application Publication
(10) Pub. No.: US 2011/0300371 A1
(43) Pub. Date: Dec. 8, 2011

(54) EPITAXIAL SUBSTRATE AND METHOD FOR PRODUCING SAME

(76) Inventors: Shuichi Omote, Tokyo (JP); Kazunari Kurita, Tokyo (JP)

(21) Appl. No.: 13/099,033

(22) Filed: May 2, 2011

(30) Foreign Application Priority Data
Jun. 3, 2010 (JP) 2010-127557

(51) Int. Cl. C30B 33/02; B32B 5/16

(52) U.S. Cl. 428/323; 117/3

(57) ABSTRACT

[Problem] An object of the present invention is to provide an epitaxial substrate and a method for producing the same capable of suppressing metal contamination and thereby reducing occurrence of white defects of a solid state imaging sensor by maintaining sufficient gettering capability during a device manufacturing process.

[Solving Means] The present invention is a method of producing an epitaxial substrate, comprising a step of growing an epitaxial layer on a silicon substrate containing carbon as a dopant to form an epitaxial substrate; and, after the formation of the epitaxial substrate, a step of applying a first thermal treatment and a second thermal treatment to the epitaxial substrate such that a density of oxygen precipitates in a surface layer of the silicon substrate constituting the epitaxial substrate is larger than a density of oxygen precipitates at a center of the silicon substrate in a thickness direction.

The present invention relates to an epitaxial substrate and a method for producing the same, and in particular, relates to an epitaxial substrate for a solid state imaging sensor for use in a digital video camera, cellular phone and the like, and a method for producing the same.

### RELATED ART

A solid state imaging sensor is produced by: pulling up a silicon single crystal using the Czochralski (CZ) process or the like; slicing the silicon single crystal to obtain a silicon substrate; forming an epitaxial layer on the silicon substrate to obtain an epitaxial substrate; and, forming a circuit on the epitaxial layer. However, when a metal is introduced into the epitaxial substrate as an impurity, the introduced metal causes an increase in dark current of an image sensor, posing a problem of significantly deteriorating electric properties of a solid state imaging sensor such as occurrence of a defect called a white defect.

A factor of the introduction of the metal into the epitaxial substrate lies in a process of forming the epitaxial substrate and a process of forming the solid state imaging sensor. The metal contaminations in the process of forming the epitaxial substrate in the former case are considered to result from heavy metal particles coming from components of a furnace for epitaxial growth, or heavy metal particles generated due to metallic corrosion of materials of pipes because of chlorine-based gas, which is used for the process. In recent years, these metal contaminations have been improved through replacement of the components of the furnace for epitaxial growth with a component made of a corrosion-resistant material or other efforts, hut it was still difficult to completely avoid the metal contaminations in the process of forming the epitaxial substrate. On the other hand, in the process of forming the solid state imaging sensor in the latter case, there is a concern about heavy metal contamination of the epitaxial substrate in the processes of ion implantation, diffusion, oxidation-thermal treatment or the like.

Therefore, conventionally, the metal contamination of the epitaxial substrate was avoided by forming a gettering sink for capturing the metals in the silicon substrate, or by using a substrate having high capability of capturing the metals (high gettering capability) such as high-concentration boron containing substrate.

To form the gettering sink in the silicon substrate, it is general to use an intrinsic gettering (IG) method in which oxygen precipitates are formed within a semiconductor substrate, or an extrinsic gettering (EG) method in which a gettering sink is formed on a rear surface of a semiconductor substrate. However, in a case of the EG method, damage such as a back side damage is formed on the rear side of the substrate, and hence there was a problem that particles are generated from the rear surface during the process of forming an epitaxial substrate or image sensor to further form a factor inducing defects in the image sensor.

WO 2009/075288 discloses a technique of an epitaxial substrate employing the IG method described above, in which a high-concentration boron containing silicon single crystal substrate containing carbon as a dopant is subjected to a thermal treatment that enhances the precipitation of the oxygen precipitates. In this technique, this thermal treatment is a thermal treatment performed at the time of forming an epitaxial layer or a thermal treatment performed under the same conditions as this thermal treatment. However, in the recent device process, in which the thermal process is performed at a lower temperature in a shorter period of time under a condition in which temperatures rapidly increase/decrease, there was a problem that the oxygen precipitates cannot be sufficiently obtained, and hence the desired gettering performance cannot be achieved.

### DISCLOSURE OF THE INVENTION

### Problems To Be Solved By the Invention

An object of the present invention is to solve the problems described above, and to provide an epitaxial substrate and a method for producing the same capable of suppressing metal contamination and thereby reducing occurrence of white defects of a solid state imaging sensor, by maintaining sufficient gettering capability during a device manufacturing process.

### Means For Solving the Problem

As a result of keen study on a technique of preventing heavy metal contamination of an epitaxial substrate, the present inventors reached an idea that it is possible to precipitate the larger number of oxygen precipitates by applying a thermal treatment that enhances the precipitation of oxygen precipitates after formation of an epitaxial layer, as compared with an epitaxial substrate that is subjected to said thermal treatment as a thermal treatment for forming the epitaxial layer; and, it is possible to concentrate the oxygen precipitates in a surface layer of a silicon substrate, by applying a predetermined thermal treatment after formation of the epitaxial layer as a pre-process before the precipitation-enhancing thermal treatment. Further, there has been revealed that it is possible to concentrate the oxygen precipitates in the surface layer of the silicon substrate more significantly by adding a predetermined amount of carbon to the silicon substrate, whereby the present inventors accomplished the present invention.

in order to achieve the object above, the present invention has the following main configurations.

(1) A method of producing an epitaxial substrate, comprising: a step of growing an epitaxial layer on a silicon substrate containing carbon as a dopant to form an epitaxial substrate; and, after the formation of the epitaxial substrate, a step of applying a first thermal treatment and a second thermal treatment to the epitaxial substrate such that a density of oxygen precipitates in a surface layer of the silicon substrate constituting the epitaxial substrate is larger than a density of oxygen precipitates at a center of the silicon substrate in a thickness direction.

(2) The method according to (1) described above, in which the surface layer of the silicon substrate extends from a depth of 5 μm to a depth of 30 μm, the depths being measured from the surface of the silicon substrate in the thickness direction.

(3) The method according to (1) described above, in which the density of oxygen precipitates in the surface layer of the silicon substrate is two times or more larger than the density of oxygen precipitates at the center of the silicon substrate in the thickness direction.

(4) The method according to (1) described above, in which the density of oxygen precipitates in the surface layer of the silicon substrate is 5×10⁵ pieces/cm² or more.

(5) The method according to (1) described above, in which the density of oxygen precipitates at the center of the silicon substrate is 3×10⁵ pieces/cm² or lower.

(6) The method according to (1) described above, in which the first thermal treatment includes: placing the epitaxial substrate in a device capable of maintaining a nitrogen-containing atmosphere therein at a temperature in a range of 500 to 700° C.; raising the temperature to between 1100 and 1300° C. at a speed of 10 to 100° C./min; keeping said temperature for 0.01 to 60 seconds; and, lowering the temperature to between 500 and 700° C. at a speed of 10 to 100° C./min.

(7) The method according to (1) described above, in which the second thermal treatment includes maintaining the epitaxial substrate in a nitrogen containing atmosphere in a temperature range of 600 to 1100° C. for 15 minutes to 15 hours.

(8) The method according to (1) described above, in which the silicon substrate has a carbon concentration in a range of 0.1×10¹⁶ to 20×10¹⁶ atoms/cm³.

(9) The method according to (1) described above, in which the silicon substrate further contains nitrogen as a dopant, and the concentration of said nitrogen is in a range of 0.5×10¹³ to 50×10¹³ atoms/cm³.

(10) The method according to (1) described above, in which, before the step of applying the first thermal treatment and the second thermal treatment to the epitaxial substrate, the silicon substrate has interstitial oxygen concentration in a range of 1.0×10¹⁸ to 2.0×10¹⁸ atoms/cm³.

(11) An epitaxial substrate having an epitaxial layer on a silicon substrate containing carbon as a dopant, in which a density of oxygen precipitates in a surface layer of the silicon substrate is larger than a density of oxygen precipitates at a center of the silicon substrate in a thickness direction.

(12) The epitaxial substrate according to (11) described above, in which the density of oxygen precipitates in the surface layer of the silicon substrate is 5×10⁵ pieces/cm² or more.

(13) The epitaxial substrate according to (11) described above, in which the density of oxygen precipitates at the center of the silicon substrate in the thickness direction is 3×10⁵ pieces/cm⁵ or lower.

### Effect of the Invention

According to the present invention, it is possible to provide an epitaxial substrate and a method for producing the same capable of suppressing metal contamination and thereby reducing occurrence of white defects of an image sensor by maintaining sufficient gettering capability during the device manufacturing process, through a step of growing an epitaxial layer on a silicon substrate containing dopant of carbon to form an epitaxial substrate; and, after this step of forming the epitaxial substrate, a thermal-treatment applying step of applying a first thermal treatment and a second thermal treatment to the epitaxial substrate such that a density of oxygen precipitates in a surface layer of the silicon substrate constituting the epitaxial substrate is larger than a density of oxygen precipitates at a center of the silicon substrate in a thickness direction.

### BRIEF DESCRIPTION OF THE DRAWINGS

FIGS. 1A through 1C are schematic sectional views for explaining a method of producing an epitaxial substrate according to the present invention.

FIG. 2 is an example of a graph showing a density distribution of oxygen precipitates in the epitaxial substrate according to the present invention,

FIG. 3 is a graph showing profiles of a density of oxygen precipitates in a thickness direction of silicon substrates of Example 1 and Comparative Examples 1 and 2.

FIG. 4 is a graph showing an IG map related to silicon substrates of Example 1 and Comparative Examples 1 and 2.

### BEST MODE CARRYING OUT THE INVENTION

Next, an embodiment of an epitaxial substrate and a method for producing the same according to the present invention will be described with reference to the drawings. FIGS. 1A through 1C are schematic sectional views for explaining a method for producing a back-illuminated image sensor according to the present invention. Note that a thickness direction in FIGS. 1A through 1C is exaggeratedly illustrated for explanation purpose.

As illustrated in FIGS. 1A through 1C, a method of producing an epitaxial substrate 100 according to the present invention includes a step of growing an epitaxial layer 2 (two layers of epitaxial layers 2a, 2h in FIGS. 1A through 1C) on a silicon substrate 1 containing dopant of carbon to form an epitaxial substrate (FIGS. 1A and 1B), and, after this step of forming the epitaxial substrate, a thermal-treatment applying step of applying a first thermal. treatment and a second thermal treatment to the epitaxial substrate such that a density of oxygen precipitates in a surface layer of the silicon substrate I constituting the epitaxial substrate is larger than a density of oxygen precipitates at a center of the silicon substrate 1 in a thickness direction (FIG. 1C). With the configuration described above, it is possible to provide an epitaxial substrate and a method of producing the same capable of suppressing metal contamination and thereby reducing occurrence of white defects of an image sensor by maintaining sufficient gettering capability during the device manufacturing process.

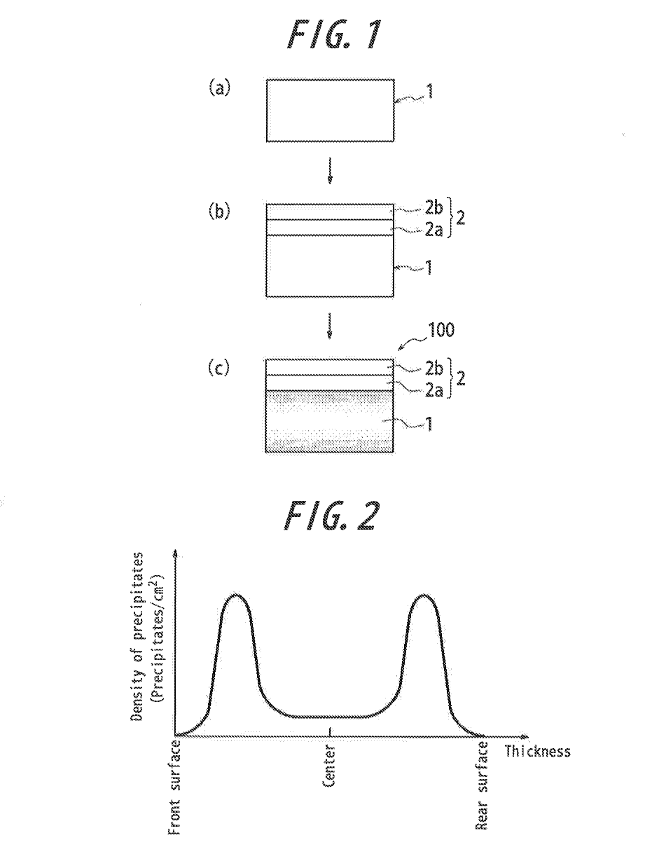

In this specification, the expression “a density of oxygen precipitates in a surface layer of the silicon substrate 1 is larger than a density of oxygen precipitates at a center of the silicon substrate 1 in a thickness direction” means that, as exemplarily illustrated in FIG. 2, a density profile of the oxygen precipitates in the thickness direction of the silicon substrate has peaks at predetermined depths from the front surface and the rear surface, respectively. In a case where the density of oxygen precipitates exhibits a so-called “letter-M” shaped distribution, a region containing oxygen precipitates with high density is formed immediately below the epitaxial layer, whereby the substrate has higher gettering capability as compared with the case where the density is uniform.

Further, the oxygen precipitate means precipitates formed by a carbon-oxygen complex (cluster), and the device manufacturing process described above means a process of forming an image sensor after the epitaxial layer growing step.

It is preferable that the silicon substrate 1 has a carbon concentration in a range of 0.1×10¹⁶ to 20×10¹⁶ atoms/cm³. This is because, in a case where the carbon concentration is less than 0.1×10¹⁶ atoms/cm³, the oxygen precipitates acting as a gettering sink cannot be sufficiently formed, and on the other hand, in a case where the carbon concentration exceeds 20×10¹⁶ atoms/cm³, a size of each of the oxygen precipitates becomes less than 50 nm, and hence, the sufficient gettering capability cannot be obtained. Note that the silicon substrate 1 may contain carbon in a solid solution state. This makes it possible to introduce said carbon into a silicon lattice in place of silicon. Carbon has an atomic radius shorter than that of silicon atom, and hence, a stress field of crystal becomes compressive stress field when the carbon is placed at the replacing position, whereby oxygen and impurities between the lattices are captured more easily by the compressive stress field. Therefore, by applying a predetermined thermal treatment to the silicon substrate, precipitates combined with oxygen and having dislocation are likely to be formed at a high density from the substituted carbon, whereby the silicon substrate 1 can obtain a high gettering effect.

The silicon substrate 1 may further contain nitrogen as dopant, and the nitrogen concentration thereof is preferably in a range of 0.5×10¹³ to 50×10¹³ atoms/cm³. This is because there is a possibility that the oxygen precipitates acting as the gettering sink cannot be sufficiently formed in a case where the nitrogen concentration thereof is less than 0.5×10¹³ atoms/cm³, and on the other hand, there is a possibility that dislocation enters the epitaxial layer in a case where the nitrogen concentration thereof exceeds 50×10¹³ atoms/cm³.

The surface layer of the silicon substrate 1 extends preferably from a depth of 5 μm to a depth of 30 μm measured from the surface of the silicon substrate in the thickness direction. The leak current or the like may occur in a case where a peak of the density of oxygen precipitates exists in a depth range of 0 μm to less than 5 μm measured from the surface of the silicon substrate in the thickness direction, so this range is formed preferably so as to be a defect-free layer. On the other hand, the sufficient gettering effect cannot be obtained in a case where the peak of the density of oxygen precipitates exists in a depth range of more than 30 μm measured from the surface of the silicon substrate in the thickness direction, to the center of the silicon substrate in the thickness direction.

Further, the density of oxygen precipitates in the surface layer of the silicon substrate 1 is preferably two times or more larger than that at the center of the silicon substrate 1 in the thickness direction. In this embodiment, the density of oxygen precipitates in the surface layer of the silicon substrate 1 refers to the maximum value of the peak. By setting the density of oxygen precipitates in the surface layer of the silicon substrate 1 two times or more larger than that at the center of the silicon substrate 1 in the thickness direction, a zone having the oxygen precipitates at the high density can be formed immediately below the epitaxial layer, whereby the sufficient gettering effect can be obtained,

The density of oxygen precipitates in the surface layer of the silicon substrate 1 is preferably 5×10⁵ pieces/cm² or more. This is because, in a case where the density of oxygen precipitates is less than 5×10⁵ pieces/cm², there is a possibility that the gettering effect is insufficient.

On the other hand, the density of oxygen precipitates at the center of the silicon substrate 1 is preferably 3×10⁵ pieces/cm² or lower. This is because, in a case where the density of oxygen precipitates exceeds 3×10⁵ pieces/cm², enhancement of the precipitation of oxygen precipitates in the surface layer may be suppressed, although the gettering effect can be obtained,

The first thermal treatment preferably includes: placing the epitaxial substrate in a device that can maintain a nitrogen-containing atmosphere therein at a temperature in a range of 500 to 700° C.; raising the temperature to between 1100 and 1300° C. at a speed of 10 to 100° C./min; maintaining the temperature for 0.01 to 60 seconds; and, lowering the temperature to between 500 and 700° C. at a speed of 10 to 100° C./min, This thermal treatment makes it possible to nitride the surface of the silicon substrate 1, introduce vacancies, and hence form a high-density vacancy-injection layer in the surface layer of the substrate.

The second thermal treatment preferably includes maintaining the epitaxial substrate in a nitrogen-containing atmosphere at a temperature range of 600 to 1100° C. for 15 minutes to 15 hours. This second thermal treatment makes it possible to form BMD having a size that does not vanish even if thermal treatment is applied in the process of forming the image sensor with the vacancies formed in the first thermal treatment being used as precipitation nuclei.

It is preferable that, before the step of applying the first thermal treatment and the second thermal treatment to the epitaxial substrate, the silicon substrate 1 has interstitial oxygen concentration in a range of 1.0×10¹⁸ to 2.0×10¹⁸ atoms/cm³. This is because, in a case where the interstitial oxygen concentration is less than 1.0×10¹⁸ atoms/cm³, there is a possibility that the precipitation of the oxygen is suppressed, and hence, the density of oxygen precipitates becomes undesirably low, and on the other hand, in a case where the interstitial oxygen concentration exceeds 2.0×10¹⁸ atoms/cm³, there is a possibility that the precipitates are excessively generated.

Further, prior to the step of forming the epitaxial substrate by to growing the epitaxial layer 2 on the silicon substrate 1 containing dopant of carbon (FIG. 1B), the method of producing an epitaxial substrate 100 according to the present invention preferably further includes a step of polishing and cleaning the silicon substrate 1, Note that the cleaning method includes an RCA cleaning in which SC-1 and SC-2 are combined, and the like.

As illustrated in FIG. 1C, the epitaxial substrate 100 according to the present invention has the epitaxial layer 2 (two layers of epitaxial layers 2a, 2b in FIG. 1C) on the silicon substrate 1 containing dopant of carbon, and, a density of oxygen precipitates in the surface layer of the silicon substrate 1 is larger than a density of oxygen precipitates at a center of the silicon substrate 1 in a thickness direction. With the configuration described above, it is possible to provide an epitaxial substrate capable of suppressing metal contamination and thereby reducing occurrence of white defects of an image sensor by maintaining sufficient gettering capability during the device manufacturing process.

Further, for the reason described above, the density of oxygen precipitates in the surface layer of the silicon substrate 1 is preferably 5×10⁵ pieces/cm² or more, and the density of oxygen precipitates at the center of the silicon substrate 1 in the thickness direction is preferably 3×10⁵ pieces/cm² or lower.

The silicon substrate 1 may be a p− substrate containing boron as a p-type impurity in a range of 4.4×10¹³ atoms/cm³ to 2.8×10¹⁷ atoms/cm³ and having resistivity in a range of 0.1Ω cm to 300Ω cm, or an n− substrate containing phosphorus as an n-type impurity in a range of 1.4×10¹³ atoms/cm³ to 7.8×10¹⁶ atoms/cm³ and having resistivity in a range of 0.1Ω cm to 300Ω cm. However, in order to enhance aggregation of oxygen precipitates, it is more preferable that the silicon substrate 1 is a p+ substrate containing boron as the p-type impurity in a range of over 2.8×10¹⁷ atoms cm³ to 1.06×10²⁰ atoms/cm³ and having resistivity in a range of 1.1 mΩ cm to less than 100 mΩ cm.

The epitaxial layer 2 preferably has two layers of epitaxial layers 2a and 2b as illustrated in FIG. 1C. In this case, it is preferable that the epitaxial layer 2a is the p++ substrate (thickness: 0.1 to 5 μm) containing boron as the p-type impurity in a range of 1.1×10¹⁹ atoms/cm³ to 1.2×10²⁰ atoms/cm³ and having resistivity in a range of 1 mΩ cm to 8 mΩ cm, and the epitaxial layer 2b is the p− substrate (thickness: 2.5 to 10 μm) containing boron as the p-type impurity in a range of 4.4×10¹³ atoms/cm³ to 2.8×10¹⁷ atoms/cm³ and having resistivity in a range of 0.1 Ω cm to 300Ω cm, or the n− substrate (thickness: 2.5 to 10 μm) containing phosphorus as the n-type impurity in a range of 1.4×10¹³ atoms/cm³ to 7.8×10¹⁶ atoms/cm³ and resistivity in a range of 0.1Ω cm to 300Ω0 cm. The reason for employing the configuration described above is to secure a depletion layer for photodiode.

It should be noted that, although not illustrated, in a case where the epitaxial layer 2 is one layer, the epitaxial layer 2 is preferably a p− substrate (thickness: 2.5 to 10 μm) containing boron as p-type impurity in a range of 4.4×10¹³ atoms/cm³ to 2.8×10¹⁷ atoms/cm³ and having resistivity in a range of 0.1Ωcm to 300Ω cm, or an n− substrate (thickness: 2.5 to 10 μm) containing phosphorus as the n-type impurity in a range of 1.4×10¹³ atoms/cm³ to 7.8×10¹⁶ atoms/cm³ and resistivity in a range of 0.1Ω cm to 300Ω cm.

It should be noted that FIGS. 1 and 2 only illustrate examples of the typical embodiment, and the present invention is not limited to this embodiment. Note that, although the epitaxial substrate according to the present invention is suitable for use in the solid state imaging sensor, it is also applicable to any substrate that requires high gettering capability, other than that for the solid state imaging sensor.

### EXAMPLE

### Example 1

In Example 1, an epitaxial substrate (thickness: 780 μm) is prepared as a sample by growing an epitaxial layer (doping element: boron, resistivity: 10Ω cm, and thickness: 5 μm) on a silicon substrate (carbon concentration: 9×10¹⁶ atoms/cm³, interstitial oxygen concentration: 1.5×10¹⁸ atoms/cm³, doping element: boron, resistivity: 10Ω cm, and thickness: 775μm) containing dopant of carbon; and then, applying a first thermal treatment and a second thermal treatment.

The first thermal treatment includes: placing the epitaxial substrate in a device that can maintain an atmosphere therein of Ar+NH₃ at a temperature of 600° C.; raising the temperature to 1200° C. at a speed of 90° C./min; keeping the temperature for 30 seconds; and, lowering the temperature to 600° C. at a speed of 70° C./min.

The second thermal treatment includes: keeping the epitaxial substrate in an atmosphere of N₂+O₂ at 600° C. for one hour; raising the temperature to 1000° C. at a speed of 3° C./min; and keeping the epitaxial substrate at a temperature of 1000° C. for two hours.

### Comparative Example 1

In Comparative Example 1, an epitaxial substrate is prepared as a sample through the method same as Example 1, except that a silicon substrate (interstitial oxygen concentration: 1.5×10¹⁸atoms/cm3, doping element: boron, resistivity: 10.5Ω cm, and thickness: 775 μm) without dopant of carbon is used in Comparative Example 1.

### Comparative Example 2

In Comparative Example 2, an epitaxial substrate is prepared as a sample through the method same as Example 1, except that the first thermal treatment is not applied in Comparative Example 2.

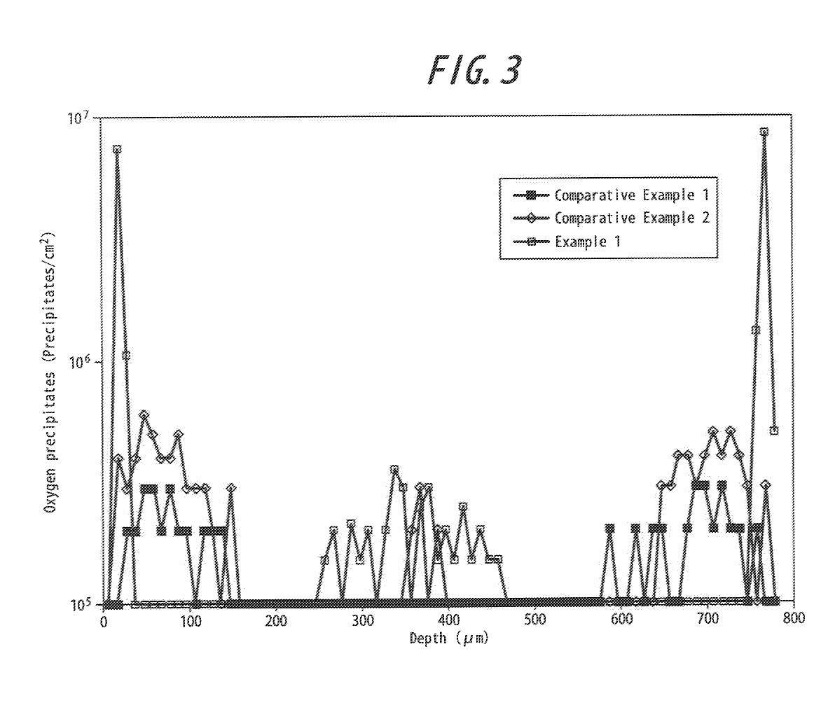

FIG. 3 is a graph showing profiles of density of oxygen precipitates in the thickness direction of the silicon substrates of Example 1 and Comparative Examples 1 and 2.As shown in FIG. 3, it can be understood that the epitaxial substrate of Example 1 according to the present invention has a larger density of oxygen precipitates in the surface layer as compared with the epitaxial substrates of Comparative Examples 1 and 2.

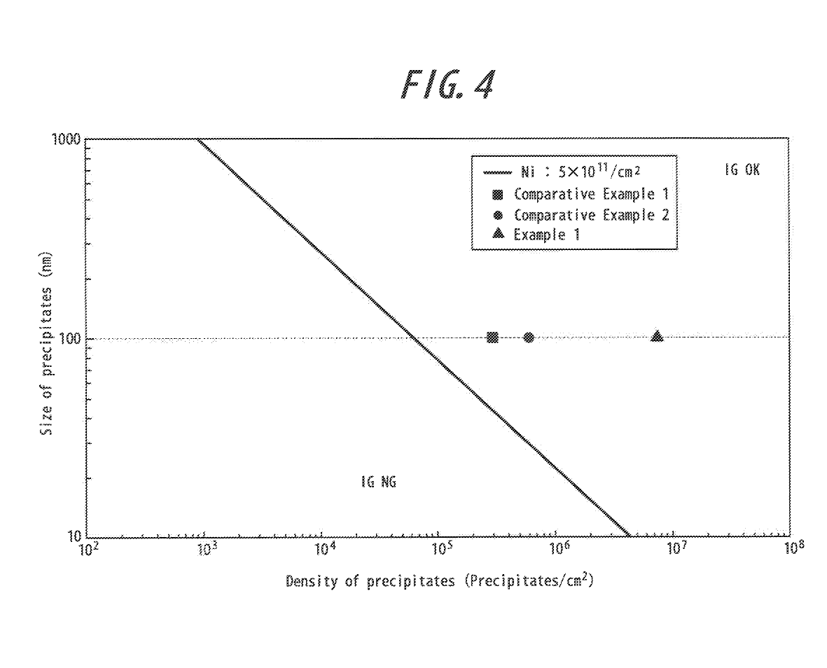

Further, FIG. 4 is an IG map illustrating a relationship between the precipitation density and the gettering. An IG line represents a boundary of the BMD size and the density, and indicates that, when Ni of 5×10¹¹ atoms/cm² is forcibly contaminated, 90% of said contamination can be gettered. In the IG map, the gettering capability for Ni of the substrate increases toward the right direction from the IG line. From the comparison on the IG map, it can be understood that Example 1 has higher gettering capability as compared with Comparative Examples 1 and 2.

### INDUSTRIAL APPLICABILITY

According to the present invention, it is possible to provide an epitaxial substrate and a method for producing the same capable of suppressing metal contamination and thereby reducing occurrence of white defects of an image sensor by maintaining sufficient gettering capability during the device manufacturing process, through a step of forming an epitaxial substrate by growing an epitaxial layer on a silicon substrate containing dopant of carbon; and, after this step of forming the epitaxial substrate, a thermal-treatment applying step of applying a first thermal treatment and a second thermal treatment to the epitaxial substrate such that a density of oxygen precipitates in a surface layer of the silicon substrate constituting the epitaxial substrate is larger than a density of oxygen precipitates at a center of the silicon substrate in a thickness direction.

### EXPLANATION OF REFERENCE NUMERAL

100 Epitaxial substrate

1 Silicon substrate

2 Epitaxial layer

1. A method of producing an epitaxial substrate, comprising:
a step of growing an epitaxial layer on a silicon substrate containing carbon as a dopant to form an epitaxial substrate; and,
after the formation of the epitaxial substrate, a step of applying a first thermal treatment and a second thermal treatment to the epitaxial substrate such that a density of oxygen precipitates in a surface layer of the silicon substrate constituting the epitaxial substrate is larger than a density of oxygen precipitates at a center of the silicon substrate in a thickness direction.

2. The method according to claim 1, wherein
the surface layer of the silicon substrate extends from a depth of 5 μm to a depth of 30 μm, the depths being measured from the surface of the silicon. substrate in the thickness direction.

3. The method according to claim 1, wherein
the density of oxygen precipitates in the surface layer of the silicon substrate is two times or more larger than the density of oxygen precipitates at the center of the silicon substrate in the thickness direction.

4. The method according to claim I, wherein
the density of oxygen precipitates in the surface layer of the silicon substrate is 5×10⁵ pieces/cm² or more.

5. The method according to claims 1, wherein
the density of oxygen precipitates at the center of the silicon substrate is 3×10⁵ pieces/cm² or lower.

6. The method according to claims 1, wherein
the first thermal treatment includes: placing the epitaxial substrate in a device capable of maintaining a nitrogen-containing atmosphere therein at a temperature in a range of 500 to 700°C.; raising the temperature to between 1100 and 1300° C. at a speed of 10 to 100° C./min; keeping said temperature for 0.01 to 60 seconds; and, lowering the temperature to between 500 and 700° C. at a speed of 10 to 100° C./min.

7. The method according to claims 1, wherein
the second thermal treatment includes maintaining the epitaxial substrate in a nitrogen-containing atmosphere in a temperature range of 600 to 1100° C. for 15 minutes to 15 hours.

8. The method according to claims 1, wherein
the silicon substrate has a carbon concentration in a range of 0.1×10¹⁶ to 20×10¹⁶ atoms/cm³.

9. The method according to claims 1, wherein
the silicon substrate further contains nitrogen as a dopant, and the concentration of said nitrogen is in a range of 0.5×10¹³ to 50×10¹³ atoms/cm³.

10. The method according to claims 1, wherein,
before the step of applying the first thermal treatment and the second thermal treatment to the epitaxial substrate, the silicon substrate has interstitial oxygen concentration in a range of 1.0×10¹⁸ to 2.0×10¹⁸ atoms/cm³.

11. An epitaxial substrate having an epitaxial layer on a silicon substrate containing carbon as a dopant, wherein
a density of oxygen precipitates in a surface layer of the silicon substrate is larger than a density of oxygen precipitates at a center of the silicon substrate in a thickness direction.

12. The epitaxial substrate according to claim 11, wherein
the density of oxygen precipitates in the surface layer of the silicon substrate is 5×10⁵ pieces/cm² or more.

13. The epitaxial substrate according to claim 11, wherein the density of oxygen precipitates at the center of the silicon substrate in the thickness direction is 3×10⁵ pieces/cm² or lower.
